(19) United States
(12) Patent Application Publication
(10) Pub. No.: US 2005/0001307 A1
(43) Pub. Date: Jan. 6, 2005

(54) [WAFER LEVEL PASSIVE COMPONENT]

(76) Inventor: Min-Lung Huang, Kaohsiung (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/710,301

(22) Filed: Jul. 1, 2004

(30) Foreign Application Priority Data
Jul. 1, 2003 (TW) 92117925

(51) Int. Cl. H01L 29/00

(52) U.S. Cl. 257/690

(57) ABSTRACT

A wafer level passive component is directly formed on an active surface of the chip. Conductive patterns and a dielectric pattern are used to form a capacitor and electrically connect to contact pads of the chip. Therefore, the internal wiring of the chip can directly connect to the wafer level passive component disposed on the active surface of the chip, increasing the electrical performance of the chip.

### CROSS REFERENCE TO RELATED APPLICATIONS

This application claims the priority benefit of Taiwan application serial no. 92117925, filed Jul. 1, 2003.

### BACKGROUND OF INVENTION

1. Field of the Invention

This invention relates to a passive component, and particularly to a wafer level passive component.

2. Brief Description of Related Art

Flip chip bonding technology distributes bonding pads over an active surface of a chip in area arrays, and turns (flips) the chip upside down to attach to a carrier after bumps has been formed respectively on the bonding pads. The bumps electrically and physically connect to bump pads on the carrier. The carrier can be a substrate or a print circuit board. Flip chip technology has been widely applied in semiconductor package industry because not only flip chip technology may be used in high-pin-count semiconductor packages but also provides advantages of small package area and shorter signal transmission path.

In order to comply with the electrical design for the semi-conductor package, a plurality of passive components such as capacitors, inductors and resistors are mounted on the substrate. The passive components further electrically connect to the chip or other electrical devices via internal wiring of the substrate. In other words, the electrical connection between the chip and the passive devices can be achieved via the bumps and the internal wiring.

In the prior art, the passive components must be individually formed and then surface mounted onto corresponding contact pads on the substrate, which increase the total costs of the flip chip packages. Alternatively, a flip-chip package substrate with built-in passive components has been proposed. That is, the passive components have been built inside the substrate during the fabrication of the substrate. Under suitable circuit design and process control, these built-in passive components may have better electrical performance than surface-mounted ones, and the packaging costs can be reduced.

Although the flip-chip package substrate with built-in passive component has improved performance and can be produced with reduced cost, the electrical connection between the chip and the passive components is still achieved through the bumps and the internal wiring of the substrate. Hence, for those passive components that need to be directly electrically connected to the chip, the flip-chip package substrate with built-in passive component cannot provide better electric performances.

### SUMMARY OF INVENTION

Therefore, it is an object of the invention to provide a wafer level passive component integrated on an active surface of a chip.

In order to achieve the above and other objectives, the wafer level passive component of the invention is suitable to be applied to a chip that has an active surface, a first contact pad, a second contact pad and a passive layer disposed on the active surface. The first and second contact pads are exposed by the passivation layer. The wafer level passive component further includes a first conductive pattern, a dielectric pattern and a second conductive pattern. The first conductive pattern is formed on the active surface and has a first connecting area and a first overlapping area. The first connecting area connects to the first contact pad and the first overlapping area lies on the passivation layer. Furthermore, the dielectric pattern is formed on the first overlapping area. The second conductive pattern is formed over the active surface and has a second connecting area and a second overlapping area. The second connecting area connects to the second contact pad. The second overlapping area is formed on the dielectric pattern and at least a part of the second overlapping area lies above the first overlapping area.

In the invention, the wafer level passive device is directly formed on the active surface of the chip. The two conductive patterns and the dielectric layer are used to form a capacitor and electrically connect to the contact pads of the chip. Therefore, the internal wiring of the chip directly connects to the passive device on the active surface of the chip, increasing the electrical performance of the chip.

### BRIEF DESCRIPTION OF DRAWINGS

FIG. 1 is a cross-sectional schematic view of a wafer level passive component according to one embodiment of the invention; and

FIG. 2 is a top schematic view of a wafer level passive component according to one embodiment of the invention.

### DETAILED DESCRIPTION

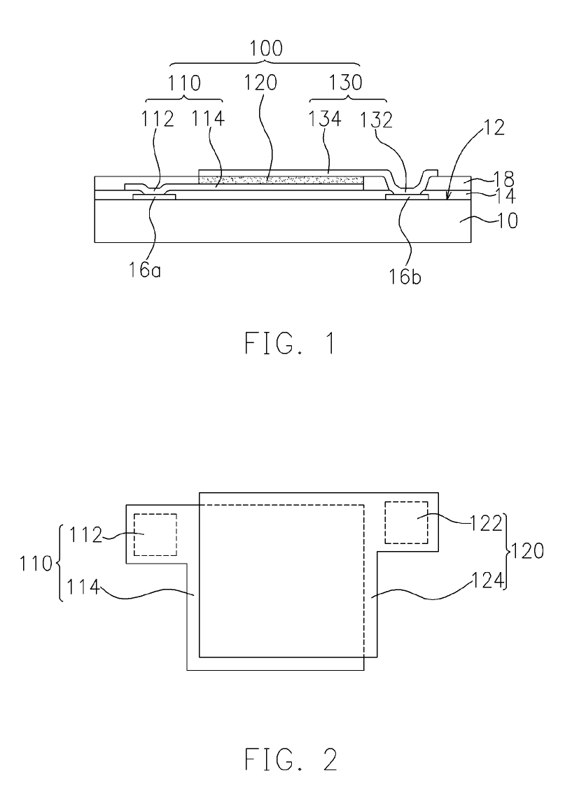

FIG. 1 is a cross-sectional view of a wafer level passive component according to one embodiment of the invention, and FIG. 2 is a top view of a wafer level passive component according to one embodiment of the invention.

Referring to FIG. 1, the chip 10 has an active surface 12. The active surface described herein means the surface of the chip 10 having active components thereon. The chip 10 further has a first contact pad 16a and a second contact pad 16b on the active surface 12 of the chip. Furthermore, the chip has a passive layer 14 covering the active surface 12 while the contact pads 16a and 16b are exposed by the passivation layer. When the chip 10 electrically connects to an external device by flip-chip technology, bumps are formed and attached on the contact pads 16a and 16b. As the chip turns (flips) upside down, the chip 10 electrically and mechanically connects to the flip-chip package substrate via the bumps.

In this embodiment, the wafer level passive component 100 includes a first conductive pattern 110, a dielectric layer (dielectric pattern) 120 and a second conductive pattern 130. The first conductive pattern 110 is formed on the active surface 12 of the chip 10, and has a first connecting area 112 and a first overlapping area 114. The first connecting area 112 connects to the first contact pad 16a, while the first overlapping area 114 lies on the passive layer 14. Furthermore, the dielectric pattern 120 is formed on the first overlapping area 140 of the first conductive pattern 110. The second conductive pattern 130 is formed over the active surface 120 and has a second connecting area 132 and a second overlapping area 134. The second connecting area 132 connects to the second contact pad 16b. The second overlapping area 134 is formed on the dielectric pattern 120 and at least a part of the second overlapping area 134 lies over the first overlapping area 114.

In the fabrication processes of the wafer level passive component 100, the first conductive pattern 110 is first formed. The first overlapping area 114 of the first conductive patter 110 lies on the passive layer 14, while the first connecting area 112 connects to the first contact pad 16a. The dielectric layer 120 is then formed on the first overlapping area 114. The dielectric layer 120 can be formed of high-dielectric-constant materials, such as aluminum oxide. The dielectric layer 120 can be formed integrally with the dielectric layer 18 or individually formed. That is, the dielectric pattern 120 and the dielectric layer 18 can be the same layer or two different layers. The dielectric layer 18 at least exposes the second contact pad 16b. Thereafter, the second conductive pattern 130 is formed over the active surface 12 and on the dielectric pattern 120. The second connecting area 132 of the second conductive pattern 130 connects to the second contact pad 16b. The second overlapping area 134 of the second conductive pattern 130 lies on the dielectric pattern 120 and corresponds to the first overlapping area 114.

In order to further ensure good connection between the bumps and the contact pads, an under bump metallurgy (UBM) layer is usually formed on the contact pads. The UBM layer usually consists of different metal or metallic layers. The fabrication of the UBM layer is well known to any skilled one in this field, and will not be described in details herein. According to the present invention, the conductive patterns may be formed after forming the UBM layer on the contact pads. Alternatively, either the first conductive pattern 110 or the second conductive pattern 130 can be formed integrally with the UBM layer. For example, the first conductive pattern 110 may be formed from one metallic layer of the UBM layer or from the UBM layer. The first and second conductive patterns may be composed of one or more metal (or metallic) layers.

As described above, the wafer level passive component is directly formed on the active surface of the chip. The two conductive patterns and the dielectric pattern are used to form a capacitor, and to electrically connect the contact pads of the chip. Therefore, the internal wiring of the chip directly connects to the wafer level passive component on the active surface of the chip, without passing through the bumps and the internal wiring of the flip-chip package substrate. Therefore, the electrical performance of the chip is enhanced. Furthermore, the wafer level passive device is not only applicable for the chip of the flip-chip package, but also for a chip with a redistribution layer thereon. For the chip with the redistribution layer thereon, the wafer level passive component can be formed in the redistribution layer.

Realizations in accordance with the present invention therefore have been described in the context of particular embodiments. These embodiments are meant to be illustrative and not limiting. Many variations, modifications, additions, and improvements are possible. Accordingly, plural instances may be provided for components described herein as a single instance. Additionally, structures and functionality presented as discrete components in the exemplary configurations may be implemented as a combined structure or component. These and other variations, modifications, additions, and improvements may fall within the scope of the invention as defined in the claims that follow.

1. A wafer level passive component, suitable for a chip, the chip at least having an active surface, a first contact pad, a second contact pad and a passivation layer, the first contact pad and the second contact pad disposed on the active surface, the passivation layer disposed on the active surface and exposing the first contact pad and the second contact pad, the wafer level passive component at least comprising:
a first conductive pattern, lying over the active surface and having a first connecting area and a first overlapping area, wherein the first connecting area connects to the first contact pad and the first overlapping area lies on the passivation layer;
a dielectric pattern, lying on the first overlapping area; and
a second conductive pattern, lying over the active surface and having a second connecting area and a second overlapping area, wherein the second connecting area connects to the second contact pad, the second overlapping area lies on the dielectric pattern, and at least a portion of the dielectric pattern is interposed between the first overlapping area and the second overlapping area.

2. The wafer level passive component of claim 1, wherein the first conductive pattern includes at least a metal layer.

3. The wafer level passive component of claim 1, wherein the second conductive pattern includes at least a metal layer.

4. The wafer level passive component of claim 1, wherein a material of the portion of the dielectric pattern is aluminum oxide.

5. The wafer level passive component of claim 1, wherein the portion of the dielectric layer is made of a material with high dielectric constant.

6. The wafer level passive component of claim 1, further comprising a dielectric layer covering a portion of the first conductive pattern.

7. The wafer level passive component of claim 1, further comprising an under bump metallurgy layer interposed between the first conductive pattern and the first contact pad.
